(19) United States
(12) Patent Application Publication
(10) Pub. No.: US 2024/0088325 A1
(43) Pub. Date: Mar. 14, 2024

(54) QUANTUM DOT LIGHT EMITTING DIODE AND METHOD FOR MANUFACTURING SAME, DISPLAY PANEL, AND DISPLAY DEVICE

(71) Applicant: BOE Technology Group Co., Ltd., Beijing (CN)

(72) Inventor: Jingwen FENG, Beijing (CN)

(21) Appl. No.: 17/766,838

(22) PCT Filed: Apr. 29, 2021
(86) PCT No.: PCT/CN2021/091119

§ 371 Date: Apr. 6, 2022

(30) Foreign Application Priority Data
May 13, 2020 (CN) 202010402249.0

(51) Int. Cl. H01L 33/06; H01L 25/075; H01L 33/00

(52) U.S. Cl. CPC H01L 33/06; H01L 25/0753; H01L 33/005; H01L 2933/0041

(57) ABSTRACT

Disclosed are a quantum dot light emitting diode and a manufacturing method therefor, a display panel and a display device, which belong to the field of display technology. The quantum dot light emitting diode comprises: an anode layer (2), a hole injection layer (3), a hole transport layer (4) and a quantum dot layer (5) which are provided in a stacked manner, a film material of the hole transport layer (4) comprising a mixture of nickel oxide and a target metal oxide, and the target metal oxide comprising at least one metal oxide other than the nickel oxide. The surface/bulk defects on the hole transport layer are passivated by doping the nickel oxide with the target metal oxide.

### CROSS-REFERENCE TO RELATED APPLICATION

This application is a U.S. national stage of international application No. PCT/CN2021/091119, filed on Apr. 29, 2021, which claims priority to the Patent Application No. 202010402249.0, filed on May 13, 2020 and entitled “QUANTUM DOT LIGHT-EMITTING DIODE AND METHOD FOR MANUFACTURING SAME, DISPLAY PANEL, AND DISPLAY DEVICE,” the contents of which are incorporated herein by reference in their entireties.

### TECHNICAL FIELD

The present disclosure relates to the field of display technologies, and in particular, relates to a quantum dot light-emitting diode and a method for manufacturing the same, a display panel, and a display device.

### BACKGROUND

With the development of quantum dot materials, constant optimization of device structures, advanced researches on efficient charge transport and the like, quantum dot light-emitting diodes (QLEDs) may surpass photoluminescence quantum dot luminescence enhancement films and quantum dot color filters in terms of display effects, and are expected to become the next-generation mainstream display technology.

### SUMMARY

The present disclosure provides a quantum dot light-emitting diode and a method for manufacturing the same, a display panel, and a display device.

In one aspect, a quantum dot light-emitting diode is provided. The quantum dot light-emitting diode includes an anode layer, a hole injection layer, a hole transport layer, and a quantum dot layer that are stacked;
wherein a film layer material of the hole transport layer includes a mixture of nickel oxide and a target metal oxide, the target metal oxide including at least one metal oxide other than the nickel oxide.

Optionally, a lattice mismatch degree between the target metal oxide and the nickel oxide is less than a preset value.

Optionally, the preset value is not greater than 1%.

Optionally, a valence band energy level of the target metal oxide is lower than a valence band energy level of the nickel oxide.

Optionally, the target metal oxide includes at least one of a magnesium oxide, a cesium oxide, and a lithium oxide.

Optionally, the target metal oxide is uniformly distributed in the hole transport layer.

Optionally, a doping ratio of the target metal oxide in the hole transport layer ranges from 1% to 50%.

Optionally, the target metal oxide is the magnesium oxide, and a doping ratio of the magnesium oxide in the hole transport layer is 3%.

In another aspect, a display panel is provided. The display panel includes any of the quantum dot light-emitting diodes according to the above aspect.

In yet another aspect, a display device is provided. The display device includes a power supply, and any of the quantum dot light-emitting diodes according to the one aspect or the display panel according to the other aspect, wherein the power supply is configured to supply power.

In still another aspect, a method for manufacturing a quantum dot light-emitting diode is provided. The method includes:
forming, on a base substrate, an anode layer, a hole injection layer, a hole transport layer, and a quantum dot layer that are stacked; wherein a film layer material of the hole transport layer includes a mixture of nickel oxide and a target metal oxide, the target metal oxide including at least one metal oxide other than the nickel oxide.

Optionally, forming the hole transport layer includes:
forming a mixed layer including the nickel oxide and the target metal oxide by co-sputtering nickel and the target metal oxide.

Optionally, forming the mixed layer including the nickel oxide and the target metal oxide by co-sputtering the nickel and the target metal oxide includes:
forming the mixed layer including the nickel oxide and the target metal oxide by co-sputtering a nickel target and a target metal oxide target under a first environment condition, wherein the first environment condition includes: an ambient gas including argon and oxygen, and an ambient temperature being in a first temperature range.

Optionally, the first temperature ranges from 0° C. to 55° C.

Optionally, upon forming the mixed layer including the nickel oxide and the target metal oxide, the method further includes.
annealing the mixed layer including the nickel oxide and the target metal oxide under a second environment condition, wherein the second environment condition includes an ambient gas being air, and an ambient temperature being in a second temperature range.

Optionally, the second temperature ranges from 100° C. to 500° C.

Optionally, forming, on the base substrate, the anode layer, the hole injection layer, the hole transport layer, and the quantum dot layer that are stacked includes:
forming the anode layer on the base substrate;
forming the hole injection layer on a side, distal from the base substrate, of the anode layer;
forming the hole transport layer on a side, distal from the base substrate, of the hole injection layer; and
forming the quantum dot layer on a side, distal from the base substrate, of the hole transport layer.

Optionally, forming, on the base substrate, the anode layer, the hole injection layer, the hole transport layer and the quantum dot layer that are stacked includes:
forming the quantum dot layer on the base substrate;
forming the hole transport layer on a side, distal from the base substrate, of the quantum dot layer;
forming the hole injection layer on a side, distal from the base substrate, of the hole transport layer; and
forming the anode layer on a side, distal from the base substrate, of the hole injection layer.

Optionally, a valence band energy level of the target metal oxide is lower than a valence band energy level of the nickel oxide.

Optionally, a lattice mismatch degree between the target metal oxide and the nickel oxide is less than a preset value.

### BRIEF DESCRIPTION OF THE DRAWINGS

FIG. 1 is a schematic structural diagram of a QLED according to an embodiment of the present disclosure:

FIG. 2 is a schematic structural diagram of another QLED according to an embodiment of the present disclosure;

FIG. 3 is a schematic structural diagram of yet another QLED according to an embodiment of the present disclosure;

FIG. 4 is a schematic diagram of the comparison of energy levels of a hole transport layer in a QLED in the related art and a hole transport layer in the QLED according to an embodiment of the present disclosure;

FIG. 5 is a schematic flowchart of a method for manufacturing a QLED according to an embodiment of the present disclosure; and

FIG. 6 is a schematic flowchart of another method for manufacturing a QLED according to an embodiment of the present disclosure.

### DETAILED DESCRIPTION

Descriptions will be made in detail to the present disclosure, examples of which are illustrated in the accompanying drawings. Throughout the accompanying drawings, same or similar reference symbols represent the same or similar components. In addition, where a detailed description of the known technology is unnecessary for the illustrated feature of the present disclosure, it will be omitted. The embodiments described hereinafter with reference to the accompanying drawings are exemplary, and are intended to explain the present disclosure, which are construed as limitations to the present disclosure.

It may be appreciated by those skilled in the art that, unless otherwise defined, all terms (including technical and scientific terms) used herein represent the same meanings as commonly understood by those of ordinary skill in the art of the present disclosure. It should further be understood that terms, such as those defined in the general dictionary, should be understood to have the meanings consistent with the meanings in the context of the prior art, and will not be interpreted in an idealized or overly formal meaning unless specifically defined as herein.

It may be understood by those skilled in the art that, unless otherwise stated, the singular forms “a,”. “an,” “the,” “said,” and “this” may further encompass plural forms. It should be further understood that the expression “include”, and “comprise” used in the description of the present disclosure mean presence of a feature, an integer, a step, an operation, an element and/or a component, but should not preclude presence or addition of one or more other features, integers, steps, operations, elements, components and/or groups thereof. The term “and/or” used herein includes all or any unit and all combinations of one or more associated listed items.

A QLED includes an anode layer, a hole injection layer, a hole transport layer (HTL), and a quantum dot layer that are stacked. A film layer material of the quantum dot layer includes a quantum dot material. Quantum dots each have a semiconductor nanostructure in which conduction band electrons, valence band holes, and excitons are bound in three spatial directions.

In the related art, the hole transport layer in the QLED is generally formed from nickel oxide (NiOx) (x is an integer greater than 1). The hole transport layer formed from the nickel oxide includes surface defects and internal defects (hereinafter simply referred to as: surface/bulk defects). For example, the surface defects include the presence of vacancies on the surface. For example, the internal defects include the presence of gaps inside. In the case that the quantum dots are directly in contact with the hole transport layer formed from the nickel oxide, the luminescent intensity of the QLED may be reduced because the surface/bulk defects on the hole transport layer may cause the excitons to be captured, and further cause quenching of excitons and affect the normal luminescence of the quantum dots.

The embodiments of the present disclosure provide a QLED. In the QLED, a hole transport layer is formed by doping other metal oxides into the nickel oxide, so as to passivate the surface/bulk defects on the hole transport layer, thereby reducing the quenching of excitons and improving the luminescent intensity of the QLED.

The technical solutions of the present disclosure and how the technical solutions of the present disclosure to solve the above technical problems are described in detail hereinafter in conjunction with specific embodiments.

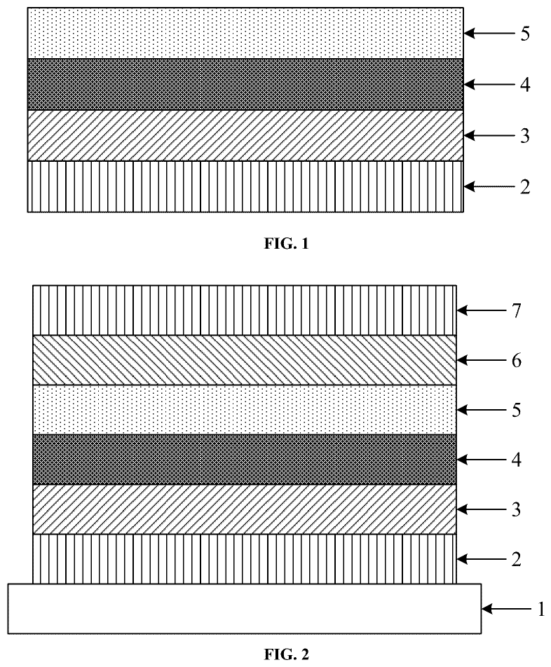

FIG. 1 is a schematic structural diagram of a QLED according to an embodiment of the present disclosure. As shown in FIG. 1, the QLED includes an anode layer 2, a hole injection layer 3, a hole transport layer 4, and a quantum dot layer 5 that are stacked.

A film layer material of the hole transport layer includes a mixture of a nickel oxide and a target metal oxide. That is, the hole transport layer is a mixed layer of the nickel oxide and the target metal oxide. The target metal oxide includes at least one metal oxide other than the nickel oxide.

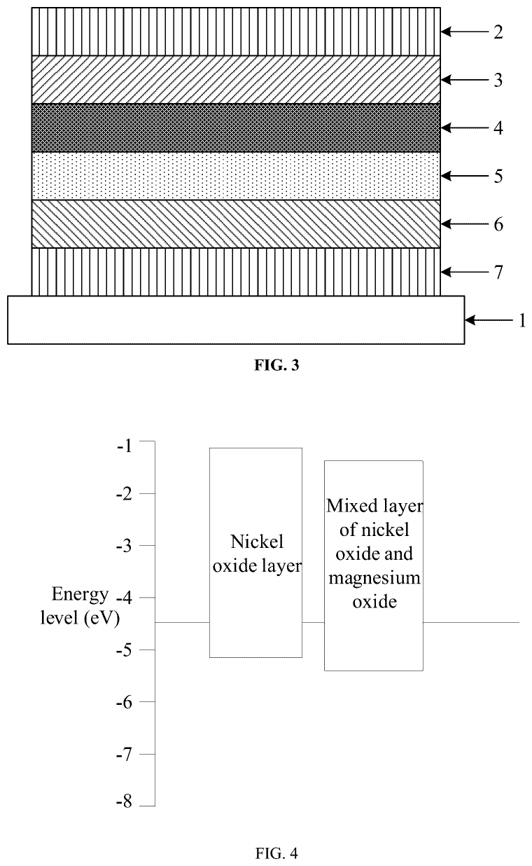

Optionally, FIG. 2 is a schematic structural diagram of another QLED according to an embodiment of the present disclosure. FIG. 3 is a schematic structural diagram of yet another QLED according to an embodiment of the present disclosure. As shown in FIG. 2 or FIG. 3, the QLED further includes an electron transport layer 6 and a cathode layer 7. Referring to FIG. 2, the QLED includes an anode layer 2, a hole injection layer 3, a hole transport layer 4, a quantum dot layer 5, the electron transport layer 6, and the cathode layer 7 that are sequentially stacked on a base substrate 1 along a direction away from the base substrate 1. Alternatively, referring to FIG. 3, the QLED includes the cathode layer 7, the electron transport layer 6, the quantum dot layer 5, the hole transport layer 4, the hole injection layer 3, and the anode layer 2 that are sequentially stacked on the base substrate 1 along a direction away from the base substrate 1.

In the embodiments of the present disclosure, the hole transport laver of the QLED is a mixed layer of the nickel oxide and a target metal oxide. By doping the target metal oxide to the nickel oxide to form the hole transport layer and using the target metal oxide as a modifier for the nickel oxide, the surface/bulk defects on the hole transport layer are passivated by means of two forms of bulk doping and surface modification. Furthermore, the problem of exciton quenching caused by direct contact between the quantum dots in the quantum dot layer and the hole transport layer is addressed, and the luminescent intensity of the QLED is improved. In addition, the service life and the photoluminescence quantum yield (PLQY) of the quantum dots can further be improved, thereby optimizing the performance of the QLED.

Optionally, a lattice mismatch degree between the target metal oxide and the nickel oxide is less than a preset value. For example, the preset value is not greater than 1%.

In the embodiments of the present disclosure, a metal oxide with a degree of lattice mismatch with the nickel oxide being less than the preset value is selected for manufacturing the hole transport layer together with the nickel oxide, which achieves a better doping effect of the nickel oxide and the metal oxide. The metal oxide may be used as a modifier for the nickel oxide better, and the surface/bulk defects on the hole transport layer are passivated by means of two forms of bulk doping and surface modification. Furthermore, the problem of exciton quenching caused by direct contact between the quantum dots in the quantum dot layer and the hole transport layer is addressed, and the luminescent intensity and the PLQY of the QLED is improved.

Optionally, a valence band energy level of the target metal oxide is lower than a valence band energy level of the nickel oxide. The valence band energy level of the target metal oxide is lower than the valence band energy level of the nickel oxide, that is, the valence band energy level of the target metal oxide is deeper than the valence band energy level of the nickel oxide. The lower (or deeper) valence band energy level represents the greater absolute value of the valence band energy level.

In the embodiments of the present disclosure, a metal oxide with a lower valence band energy level than the valence band energy level of the nickel oxide is selected for manufacturing the hole transport layer together with the nickel oxide. Compared with a hole transport layer formed from the nickel oxide in the related art, the valence band energy level of the hole transport layer according to the embodiments of the present disclosure is lower, which can reduce a hole injection barrier of the hole transport layer. Therefore, the number of holes accumulated between the hole transport layer and the quantum dot layer is reduced (that is, the accumulation of holes is reduced), such that more holes enter the quantum dot layer to form excitons together with electrons to emit light, thereby further improving the luminescent intensity and the PLQY of the QLED. In addition, where a larger number of electrons are present in the quantum dot layer, carrier balance in the quantum dot layer can further be achieved.

Optionally, the target metal oxide includes at least one of a magnesium oxide (MgO), a cesium oxide (Cs₂O), and a lithium oxide (Li₂O). That is, the target metal oxide may be the magnesium oxide, the cesium oxide, or the lithium oxide; or may be a mixture of at least two of the magnesium oxide, the cesium oxide, or the lithium oxide. A lattice mismatch degree between the magnesium oxide, the cesium oxide or the lithium oxide and the nickel oxide is less than 1%. The lattice mismatch degree between the magnesium oxide and the nickel oxide is 0.8%. A valence band energy level of each of the magnesium oxide, the cesium oxide and the lithium oxide is also lower than a valence band energy level of the nickel oxide, and the valence band energy level of the magnesium oxide is 0.9 electron volts (eV) lower than the valence band energy level of the nickel oxide.

In the embodiments of the present disclosure, a metal oxide with a degree of lattice mismatch with the nickel oxide being less than a preset value and with a valence band energy level being lower than the valence band energy level of the nickel oxide is selected for manufacturing the hole transport layer together with the nickel oxide. The doping effect of the nickel oxide and the metal oxide is better, and thus surface/bulk defects on the hole transport layer better are passivated. Furthermore, the problem of exciton quenching caused by direct contact between the quantum dots in the quantum dot layer and the hole transport layer is addressed, and the luminescent intensity and the PLQY of the QLED is improved. In addition, the valence band energy level of the hole transport layer is reduced, and the hole injection barrier of the hole transport layer is reduced. Therefore, the number of holes accumulated between the hole transport layer and the quantum dot layer is reduced, such that more holes enter the quantum dot layer to form excitons together with electrons to emit light, thereby further improving the luminescent intensity and the PLQY of the QLED. In addition, where a larger number of electrons are present in the quantum dot layer, carrier balance in the quantum dot layer is further be achieved.

It is worth noting that, in the embodiments of the present disclosure, a metal oxide with a degree of lattice mismatch with the nickel oxide being less than a preset value and/or with a valence band energy level being lower than the valence band energy level of the nickel oxide is selected in the case where the target metal oxide is selected. In addition to the above magnesium oxide, cesium oxide, and lithium oxide, other metal oxides that meet conditions may be used to manufacture the hole transport layer together with the nickel oxide. The specific type of the selected metal oxide is not limited in the embodiments of the present disclosure.

Optionally, the target metal oxide is uniformly distributed in the hole transport layer. That is, the target metal oxide is uniformly mixed with the nickel oxide. A better doping effect is achieved, such that the surface/bulk defects on the hole transport layer are passivated.

Optionally, a doping ratio of the target metal oxide into the hole transport layer ranges from 1% to 50%. Therefore, a better doping effect is achieved. For example, a doping ratio of the target metal oxide in the hole transport layer may be 3%.

The principle of improving the performance of the QLED in the embodiments of the present disclosure is described hereinafter by taking the doping of magnesium oxide into nickel oxide as an example.

For example, FIG. 4 is a schematic diagram of the comparison of energy levels of a hole transport layer in a QLED in the related art and a hole transport layer in a QLED according to an embodiment of the present disclosure. An ordinate represents an energy level with the unit of eV. The hole transport layer in the related art is a nickel oxide layer. In the embodiment of the present disclosure, the hole transport layer is a mixed layer of the nickel oxide and the magnesium oxide. The bottom of a rectangular box in FIG. 4 represents a magnitude of the valence band energy level. As shown in FIG. 4, the valence band energy level of the nickel oxide layer is −5.2 eV. Because the valence band energy level of the magnesium oxide is lower than the valence band energy level of the nickel oxide, the valence band energy level of the mixed layer of the nickel oxide and the magnesium oxide is lower than the valence band energy level of the nickel oxide layer. Therefore, the valence band energy level of the mixed layer of the nickel oxide and the magnesium oxide is lower than −5.2 eV. Because the valence band energy level of the mixed layer of the nickel oxide and the magnesium oxide is lower than the valence band energy level of the nickel oxide layer, the hole injection barrier of the mixed layer of the nickel oxide and the magnesium oxide is less than the valence band energy level of the nickel oxide layer. Because the hole transport layer in the embodiment of the present disclosure has a less hole injection barrier than the hole transport layer in the related art, more holes enter the quantum dot layer to form excitons together with electrons to emit light, thereby further improving the luminescent intensity and the PLQY of the QLED.

Optionally, the QLED according to the embodiments of the present disclosure may be a QLED containing cadmium (Cd) or a QLED not containing cadmium.

In summary, according to the QLED provided by the embodiments of the present disclosure, by doping the target metal oxide to the nickel oxide to form the hole transport layer and using the target metal oxide as a modifier for the nickel oxide, the surface/bulk defects on the hole transport layer are passivated by means of two forms of bulk doping and surface modification. Furthermore, the problem of exciton quenching caused by direct contact between the quantum dots in the quantum dot layer and the hole transport layer is addressed, and the luminescent intensity of the QLED is improved. In addition, the service life and the PLQY of the quantum dots can further be improved, thereby improving the performance of the QLED.

In some optional embodiments, a metal oxide with a degree of lattice mismatch with the nickel oxide being less than the preset value is selected for manufacturing the hole transport layer together with the nickel oxide, which achieves a better doping effect of the nickel oxide and the metal oxide. The metal oxide may be used as a modifier for nickel oxide better, and the surface/bulk defects on the hole transport layer are passivated by means of two forms of bulk doping and surface modification. Furthermore, the problem of exciton quenching caused by direct contact between the quantum dots in the quantum dot layer and the hole transport layer is addressed, and the luminescent intensity and the PLQY of the QLED is improved.

In some optional embodiments, a metal oxide with a lower valence band energy level than the valence band energy level of the nickel oxide is selected for manufacturing the hole transport layer together with the nickel oxide. Compared with a hole transport layer formed from the nickel oxide in the related art, the valence band energy level of the hole transport layer according to the embodiments of the present disclosure is lower, which can reduce a hole injection barrier of the hole transport layer. Therefore, the number of holes accumulated between the hole transport layer and the quantum dot layer is reduced (that is, the accumulation of holes is reduced), such that more holes enter the quantum dot layer to form excitons together with electrons to emit light, thereby further improving the luminescent intensity and the PLQY of the QLED. In addition, where a larger number of electrons are present in the quantum dot laver, carrier balance in the quantum dot layer can further be achieved.

Based on the same inventive concept, an embodiment of the present disclosure further provides a display panel. The display panel includes the QLED according to the embodiments of the present disclosure.

Optionally, the display panel may be any product or component having a display function, such as an electronic paper, a mobile phone, a tablet computer, a television, a display, a laptop computer, a digital photo frame, or a navigator.

Based on the same inventive concept, an embodiment of the present disclosure further provides a display device. The display device includes a power supply, and the QLED according to the embodiments of the present disclosure or the display panel according to the embodiments of the present disclosure. The power supply is configured to supply power. The power supply may be a power source.

Optionally, the display device may be any product or component having a display function, such as an electronic paper, a mobile phone, a tablet computer, a television, a display, a laptop computer, a digital photo frame, or a navigator.

Based on the same inventive concept, an embodiment of the present disclosure further provides a method for manufacturing a QLED. The method includes the following processes: forming, on a base substrate, an anode layer, a hole injection layer, a hole transport layer, and a quantum dot layer that are stacked. A film layer material of the hole transport layer includes a mixture of nickel oxide and a target metal oxide. The target metal oxide includes at least one metal oxide other than the nickel oxide. According to this method, the QLED shown in FIG. 1 may be manufactured.

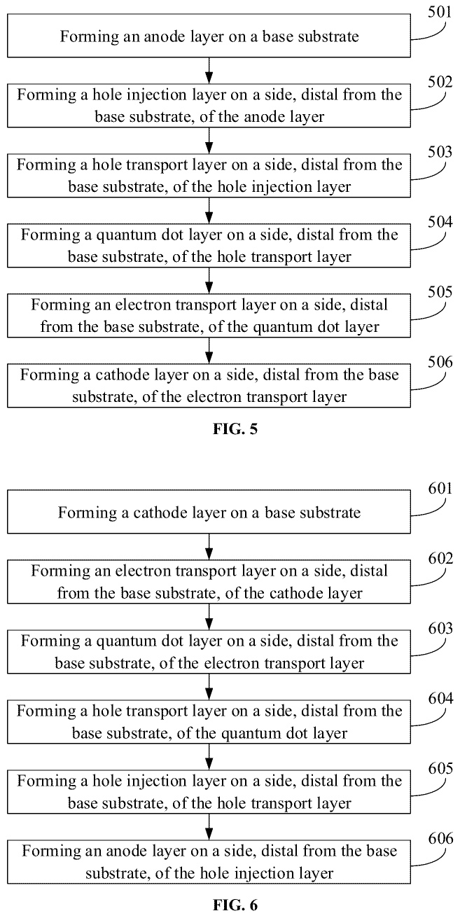

In an optional embodiment of the present disclosure, the QLED shown in FIG. 2 may be manufactured by the method for manufacturing the QLED according to the embodiment of the present disclosure. FIG. 5 is a schematic flowchart of a method for manufacturing a QLED according to an embodiment of the present disclosure. Referring to FIG. 5, the method includes the following working processes.

In S501, an anode layer is formed on a base substrate.

Optionally, a material of the base substrate is glass. Prior to forming the anode layer on the base substrate, the base substrate is cleaned first, and then the anode layer is formed on the base substrate by vapor deposition on an indium tin oxide (ITO).

In S502, a hole injection layer is formed on a side, distal from the base substrate, of the anode layer.

Optionally, a hole injection material is PEDOT: PSS. PEDOT: PSS is an aqueous solution of a high molecular polymer with high electrical conductivity. Based on different formulations, aqueous solutions with different conductivities may be obtained. PEDOT: PSS is composed of PEDOT and PSS. PEDOT is a polymer of EDOT (3,4-ethylenedioxythiophene monomer), and PSS is sodium polystyrene sulfonate.

Optionally, the hole injection layer is formed by spin coating and depositing the hole injection material on the side, distal from the base substrate, of the anode layer.

In S503, a hole transport layer is formed on a side, distal from the base substrate, of the hole injection layer.

Optionally, a mixed layer including the nickel oxide and the target metal oxide is formed on the side, distal from the base substrate, of the hole injection layer, by co-sputtering nickel and the target metal oxide. Co-sputtering generally means that two or more targets are sputtered simultaneously.

In the embodiments of the present disclosure, the hole transport layer is formed by co-sputtering the nickel and the target metal oxide, such that a doping depth of the target metal oxide is equal to a sputtering thickness of the nickel oxide. In this manner, the target metal oxide is doped when forming the nickel oxide, such that the target metal oxide is uniformly doped in the nickel oxide. For example, the doping of the magnesium oxide and the formation of the nickel oxide are carried out simultaneously, and the sputtered magnesium oxide is uniformly doped in the nickel oxide.

For example, a mixed layer including the nickel oxide and the target metal oxide is formed by co-sputtering a nickel target and a target metal oxide target under a first environment condition. The first environment condition includes an ambient gas including argon (Ar) and oxygen (O₂), and an ambient temperature being in a first temperature range. Optionally, the first temperature ranges from 0° C. to 55° C.

In the embodiments of the present disclosure, in the environment of argon and oxygen, the nickel and the target metal oxide are co-sputtered on the side, distal from the base substrate, of the hole injection layer, and the target metal oxide is doped in the process of reacting nickel with oxygen to form the nickel oxide, which can ensure the doping depth and doping uniformity of the target metal oxide.

Optionally, in the case that the mixed layer including the nickel oxide and the target metal oxide is formed on the side, distal from the base substrate, of the hole injection layer, the mixed layer including the nickel oxide and the target metal oxide may further be subjected to annealing treatment in a second environment condition. The second environment condition includes an ambient gas being air, and an ambient temperature being in a second temperature range. Optionally, the second temperature ranges from 100° C. to 500° C.

In the embodiments of the present disclosure, the annealing treatment of the mixed layer including the nickel oxide and the target metal oxide can improve the crystallinity of the mixed layer, thereby improving the structural stability of the prepared hole transport layer.

In 504, a quantum dot layer is formed on a side, distal from the base substrate, of the hole transport layer.

Optionally, the quantum dot layer is formed by spin coating and depositing a quantum dot material on the side, distal from the base substrate, of the hole transport layer.

Optionally, upon process 504, the method further includes the following processes.

In 505, an electron transport layer is formed on a side, distal from the base substrate, of the quantum dot layer.

Optionally, a material of the electron transport layer includes zinc oxide (ZnO) nanoparticles. Optionally, the electron transport layer is deposited on the side, distal from the base substrate, of the quantum dot layer by spin coating.

In 506, a cathode layer is formed on a side, distal from the base substrate, of the electron transport layer.

Optionally, a material of the cathode layer includes an aluminum (Al). Optionally, the cathode layer is formed on the side, distal from the base substrate, of the electron transport layer by vapor deposition.

Optionally, the cathode layer is a metal thin layer, and a thickness of the cathode layer ranges from 500 to 1000 nanometers.

Upon formation of the cathode layer, the QLED shown in FIG. 2 may be manufactured by further encapsulation.

In the above processes, the hole injection layer, the quantum dot layer, the electron transport layer, and the cathode layer may further be prepared by inkjet printing, which is not limited in the embodiments of the present disclosure.

In another optional embodiment of the present disclosure, the QLED shown in FIG. 3 may be prepared by the method for manufacturing the QLED according to the embodiment of the present disclosure. FIG. 6 is a schematic flowchart of another method for manufacturing a QLED according to an embodiment of the present disclosure. Referring to FIG. 6, the method includes the following processes.

In 601, a cathode layer is formed on the base substrate.

In 602, an electron transport layer is formed on a side, distal from the base substrate, of the cathode layer.

In 603, a quantum dot layer is formed on a side, distal from the base substrate, of the electron transport layer.

In 604, a hole transport layer is formed on a side, distal from the base substrate, of the quantum dot layer.

In 605, a hole injection layer is formed on a side of the hole transport layer away from the base substrate.

In 606, an anode layer is formed on a side, distal from the base substrate, of the hole injection layer.

Upon formation of the anode layer, the QLED shown in FIG. 3 may be manufactured by further encapsulation.

The manufacturing methods for each of the film layers in processes 601 to 606 may refer to S501 to S506, which are not repeated in the embodiments of the present disclosure.

It is worth noting that the structures and functions of the film layers involved in the method embodiments of the present disclosure may refer to the relevant descriptions of the above-mentioned structure embodiments, which are not repeated one by one in the embodiments of the present disclosure.

In summary, according to the method for manufacturing the QLED provided by the embodiments of the present disclosure, by doping the target metal oxide to the nickel oxide to form the hole transport layer and using the target metal oxide as a modifier for the nickel oxide, the surface/bulk defects on the hole transport layer are passivated by means of two forms of bulk doping and surface modification. Furthermore, the problem of exciton quenching caused by direct contact between the quantum dots in the quantum dot layer and the hole transport layer is addressed, and the luminescent intensity of the QLED is improved. In addition, the service life and the PLQY of the quantum dots can further be improved, thereby improving the performance of the QLED.

In an optional embodiment, a metal oxide with a degree of lattice mismatch with the nickel oxide being less than the preset value is selected for manufacturing the hole transport layer together with the nickel oxide, which achieves a better doping effect of the nickel oxide and the metal oxide. The metal oxide may be used as a modifier for the nickel oxide better, and the surface/bulk defects on the hole transport layer are passivated by means of two forms of bulk doping and surface modification. Furthermore, the problem of exciton quenching caused by direct contact between the quantum dots in the quantum dot layer and the hole transport layer is addressed, and the luminescent intensity and the PLQY of the QLED is improved.

In some optional embodiments, a metal oxide with a lower valence band energy level than the valence band energy level of the nickel oxide is selected for manufacturing the hole transport layer together with the nickel oxide. Compared with a hole transport layer formed from the nickel oxide in the related art, the valence band energy level of the hole transport layer according to the embodiments of the present disclosure is lower, which reduces a hole injection barrier of the hole transport layer. Therefore, the number of holes accumulated between the hole transport layer and the quantum dot layer is reduced (that is, the accumulation of holes is reduced), such that more holes enter the quantum dot layer to form excitons together with electrons to emit light, thereby further improving the luminescent intensity and the PLQY of the QLED. In addition, where a larger number of electrons are present in the quantum dot layer, carrier balance in the quantum dot layer is further be achieved.

It may be understood by those skilled in the art that steps, measures and solutions in various operations, methods and processes discussed in the present disclosure may be alternated, modified, combined or deleted. Furthermore, other processes, measures and solutions, with the various operations, methods and processes discussed in the present disclosure, may further be alternated, modified, rearranged, split, combined or deleted. Furthermore, steps, measures and solutions in the prior art, with the various operations, methods and processes discussed in the present disclosure, may further be alternated, modified, rearranged, split, combined or deleted.

In the description of the present disclosure, it should be understood that the orientation or position relations indicated by terms of “central,” “upper,” “lower,” “front,” “rear,” “left.” “right,” “vertical,” “horizontal.” “top,” “bottom,” “inner,” “outer,” and the like are based on orientation or the position relations shown in the accompanying drawings, and are only intended to describe the present disclosure conveniently, but not indicate or imply that referred devices or elements must include particular orientations or be constructed and operated with the particular orientation, such that they cannot be construed as limiting of the present disclosure.

In the description of the present disclosure, unless otherwise stated, the term “at least one” means one or more, the term “a plurality of” means two or more.

In the description of this specification, the particular features, structures, materials or characteristics may be integrated with any one or more embodiments or examples in a proper manner.

It should be understood that although the various processes in the flowchart of the accompanying drawings are sequentially displayed as indicated by the arrows, these processes are not necessarily performed in the order indicated by the arrows. Otherwise explicitly stated herein, the execution of these processes is not strictly limited, and may be performed in other sequences. Furthermore, at least some of the processes in the flowchart of the accompanying drawings may include a plurality of sub-processes or stages, which are not necessarily performed simultaneously, but may be performed at different moment The execution order thereof is also not necessarily performed sequentially, but may be performed in turn or alternately with at least a portion of other processes or sub-processes or stages of other processes.

The above description is only some embodiments of the present disclosure, and it should be noted that those skilled in the art may further make several improvements and modifications without departing from the principles of the present disclosure, which should be considered as the protection scope of the present disclosure.

1. A quantum dot light-emitting diode, comprising an anode layer, a hole injection layer, a hole transport layer, and a quantum dot layer that are stacked;
wherein a film layer material of the hole transport layer comprises a mixture of a nickel oxide and a target metal oxide, the target metal oxide comprising at least one metal oxide other than the nickel oxide.

2. The quantum dot light-emitting diode according to claim 1, wherein a lattice mismatch degree between the target metal oxide and the nickel oxide is less than a preset value.

3. The quantum dot light-emitting diode according to claim 2, wherein the preset value is not greater than 1%.

4. The quantum dot light-emitting diode according to claim 1, wherein a valence band energy level of the target metal oxide is lower than a valence band energy level of the nickel oxide.

5. The quantum dot light-emitting diode according to claim 1, wherein the target metal oxide comprises at least one of a magnesium oxide, a cesium oxide, and a lithium oxide.

6. The quantum dot light-emitting diode according to claim 1, wherein the target metal oxide is uniformly distributed in the hole transport layer.

7. The quantum dot light-emitting diode according to claim 1, wherein a doping ratio of the target metal oxide in the hole transport layer ranges from 1% to 50%.

8. The quantum dot light-emitting diode according to claim 7, wherein the target metal oxide is the magnesium oxide, and a doping ratio of the magnesium oxide in the hole transport layer is 3%.

9. A display panel, comprising the quantum dot light-emitting diode as defined in claim 1.

10. A display device, comprising a power supply, and the quantum dot light-emitting diode as defined in claim 1;
wherein the power supply is configured to supply power.

11. A method for manufacturing a quantum dot light-emitting diode, comprising:
forming, on a base substrate, an anode layer, a hole injection layer, a hole transport layer, and a quantum dot layer that are stacked; wherein a film layer material of the hole transport layer comprises a mixture of a nickel oxide and a target metal oxide, the target metal oxide comprising at least one metal oxide other than the nickel oxide.

12. The method according to claim 11, wherein forming the hole transport layer comprises:
forming a mixed layer comprising the nickel oxide and the target metal oxide by co-sputtering nickel and the target metal oxide.

13. The method according to claim 12, wherein forming the mixed layer comprising the nickel oxide and the target metal oxide by co-sputtering the nickel and the target metal oxide comprises:
forming the mixed layer comprising the nickel oxide and the target metal oxide by co-sputtering a nickel target and a target metal oxide target under a first environment condition, wherein the first environment condition comprises: an ambient gas comprising argon and oxygen, and an ambient temperature being in a first temperature range.

14. The method according to claim 13, wherein the first temperature ranges from 0° C. to 55° C.

15. The method according to claim 12, wherein upon forming the mixed layer comprising the nickel oxide and the target metal oxide, the method further comprises:
annealing the mixed layer comprising the nickel oxide and the target metal oxide under a second environment condition, wherein the second environment condition comprises an ambient gas being air, and an ambient temperature being in a second temperature range.

16. The method according to claim 15, wherein the second temperature ranges from 100° C. to 500° C.

17. The method according to claim 11, wherein forming, on the base substrate, the anode layer, the hole injection layer, the hole transport layer, and the quantum dot layer that are stacked comprises:
forming the anode layer on the base substrate;
forming the hole injection layer on a side, distal from the base substrate, of the anode layer;
forming the hole transport layer on a side, distal from the base substrate, of the hole injection layer; and
forming the quantum dot layer on a side, distal from the base substrate, of the hole transport layer.

18. The method according to claim 11, wherein forming, on the base substrate, the anode layer, the hole injection layer, the hole transport layer and the quantum dot layer that are stacked comprises:
forming the quantum dot layer on the base substrate;
forming the hole transport layer on a side, distal from the base substrate, of the quantum dot layer;
forming the hole injection layer on a side, distal from the base substrate, of the hole transport layer; and
forming the anode layer on a side, distal from the base substrate, of the hole injection layer.

19. The method according to claim 11, wherein a valence band energy level of the target metal oxide is lower than a valence band energy level of the nickel oxide.

20. The method according to claim 11, wherein a lattice mismatch degree between the target metal oxide and the nickel oxide is less than a preset value.
